(19) United States
(12) Patent Application Publication
(10) Pub. No.: US 2007/0063353 A1
(43) Pub. Date: Mar. 22, 2007

(54) PARTIALLY BONDING STRUCTURE FOR A POLYMER AND A CHIP

(75) Inventors: Jung-Hung Wen, Hsinchu (TW); Cheng-Chung Fu, Hsinchu (TW)

Correspondence Address: JOHN CHEN, ROOM 303, 3F, NO. 25, SEC. 1, CHANGAN E. ROAD, TAIPEI (R.O.C.), 10441, TW

(73) Assignee: ANALOG INTEGRATIONS CORP., Hsinchu (TW)

(21) Appl. No.: 11/532,115

(22) Filed: Sep. 15, 2006

(30) Foreign Application Priority Data
Sep. 19, 2005 (TW) 094132253

(51) Int. Cl. H01L 23/52

(52) U.S. Cl. 257/777

(57) ABSTRACT

The present invention provides a partially bonding structure for a Polymer and a chip, comprising a substrate, a metal layer and a Polymer. The Polymer includes the characters, such as high uniformity, good flexibility, different hydrophilicity, low stress, low melting point, and high hermeticity, to be applied to the standard semiconductor manufacture process. The Polymer is to accomplish good uniformity in spin-coating or chemical vapor deposition (CVD) method at low temperature. The metal layer or the extremely thin metal layer of the circuit of the substrate is winded to surround the lateral side of the substrate to increase the current density. And next, it is partially heated to generate an adequate temperature to form the hermetic bonding of the Polymer and the substrate instantly. As a result, the partial heating effect can be accomplished without affecting the characters of the circuit of the chip.

### BACKGROUND OF THE PRESENT INVENTION

1. Field of Invention

The invention relates to a partial bonding structure for Polymer and chips, more particularly to a lowtemperatureand-stress polymer capable of partially bonding with a chip.

2. Description of Related Arts

The prior arts include :(1) anodic boding method, processing in the high temperature and voltage situations; (2) eutectic melting-point bonding method, heated to the eutectic point and contaminating much more than the other methods; (3) organic materials bonding method, with low strength in the bonding area. The chip bonding technology of the current semiconductor packaging process employs the poly resin package, including the first substrate, the second substrate, a poly resin materials. At first, a circuit is laid out on the first substrate, and the bonding areas of the two substrates are aligned. Next, The poly resin materials is spincoated between the two substrates, and baked in an appropriate temperature to dehydrate and remove a part of the solvent. At last, a bonding machine finishes the bonding process of the chip by pressurizing with the press to bond the fist and second substrates.

The volume of the bonding structure generated in the poly resin bonding method of the prior art is too big, and the stress between the circuits is also too large. It is restricted in organism compatibility when implanted into the human bodies, and not suitable for biomedical analysis. in addition, the employed chip bonding technology of the prior art includes (4) direct chip bonding method, referring to the U.S. Pat. No. 6,225,154. As shown in FIG. 1A, the first silicon chip 1 includes a circuit 2 spin-coated on the first silicon chip 1. A glass layer 3 includes a layer of compound solvent on the first substrate 1 in spin-on-glass (SOG) method, and is baked in a low temperature to dehydrate and remove a part of the solvent. As shown in FIG. 1B, the second silicon chip and the glass layer 3 are bonded together at an appropriate temperature. There should be very smooth surfaces to employ this method. (5) photo resist partial-chip-bonding method referring to R.O.C. publish No. 507,345, as shown in FIG. 2A, the first substrate 5 and the second substrate 6 are placed in a vacuum cavity 70 of a bonding machine 7 and the vacuum cavity 70 is vacuumed. The bonding area 51a corresponding to the first substrate 5 and the bonding area 61a corresponding to the second substrate 6 are separated by a separating plate 71. A heater 72 is employed to heat under 200° C. The separating plate 71 is removed and pressure is added under 100 N to proceed with a pressurizing process. As shown in FIG. 2B, it is a diagram for finishing bonding. After the bonding area 51 of the first substrate 5 and the bonding area 61 of the second substrate 61 are bonded correspondingly, the new bonding area 8 is formed. For the photo resist bonding method, the bonding area has to be activated when the photo resist layer is the negative photo resist layer to remove the cross linking of the bonding area. The bonding process is more complex.

Therefore, the present invention provides a partial bonding structure for the Polymer and chips to overcome the drawbacks of the prior arts

### SUMMARY OF THE PRESENT INVENTION

An object of the present invention is to provide a partial bonding structure for Polymer and chips comprising Polymer and a substrate to achieve partial chip-bonding technology at low temperature.

Another object of the present invention is to provide a partial bonding structure for Polymer and chips by employing a metal layer of the substrate as a heating conductor and employing the current to generate an appropriate temperature to accomplish partially hermetic bonding between the Polymer and the substrate instantly without affecting the characters of the internal circuits and the other materials.

Another object of the present invention is to provide a partial bonding structure for Polymer and chips by extremely thinning a metal to increase the current density and then winding the metal layer to surround the lateral side of the substrate to form a heating conductor and accomplish the instant partial hermetic bonding for the Polymer layer and the substrate without affecting the characters of the internal circuits and the other materials.

Another object of the present invention is to provide a partial bonding structure for Polymer and chips by employing Polymer to form a cavity and employing the cavity and lateral area of the substrate to accomplish the effective bonding so that the structure of the chip can operate unrestrained. Therefore, it can be effectively applied to the inertia sensor, pressure sensor, and fluid control.

Another object of the present invention is to provide a partial bonding structure for Polymer and chips without changing the physical design of the partial bonding structure of the Polymer and chips. The metal layer employs the multi-layer metal process, and the external magnetic field or the external inductive interaction is employed to accomplish the partial chip bonding.

Another object of the present invention is to provide a partial bonding structure for Polymer and chips employing the placement of the metal layer to accomplish the partial heating without affecting the chips and changing the physical design of the partial bonding structure of the Polymer and chips.

Another object of the present invention is to provide a partial bonding structure for Polymer and chips without changing the physical design of the partial bonding structure of the Polymer and chips. The characters of the polymer, such as high informality, good flexibility, different hydrophilicity, low stress, low melting point, and high hermeticity, are employed to bond the Polymer and chips to form the objects with organism compatibility, fit for biomedical analysis.

Another object of the present invention is to provide a partial bonding structure for Polymer and chips without changing the physical design of the partial bonding structure of the Polymer and chips. The substrate is selected from one of the group consisting of silicon, gallium arsenide, silicon carbide, gallium nitride, and sapphire.

Accordingly, in order to accomplish the one or some or all above objects, the present invention provides a partial bonding structure for Polymer and chips, comprising:

a substrate, comprising a circuit layout on the substrate;

a Polymer layer, farmed above the substrate; and

a metal layer, comprising a extremely fine metal layer to work as a heating conductor surrounding the substrate and employing the current to generate an adequate temperature to accomplish instant partial hermetic bonding of the Polymer and the substrate without affecting the internal circuit.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

FIG. 1A-1B are the diagrams of the d irectly bonding method of the prior art.

FIG. 2A is the diagrams of the photo-resist-layer bonding method of the prior art.

FIG. 2B is the analytic diagram of the partially bonding structure of the preferred embodiment of the present invention.

FIG. 3B is the top view diagram of the partial chip structure of the preferred embodiment of the present invention.

FIG. 3C is the diagram of the cavity of the present invention.

FIG. 3D is the diagram of the multi-layer metal structure of the present invention.

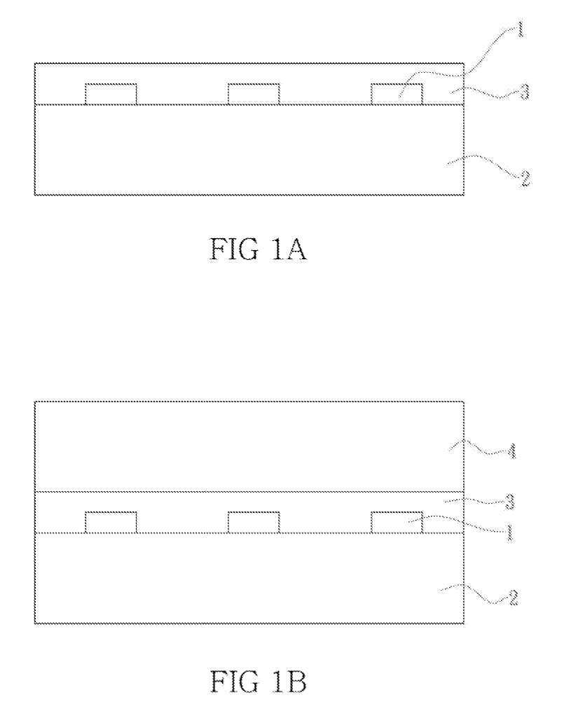

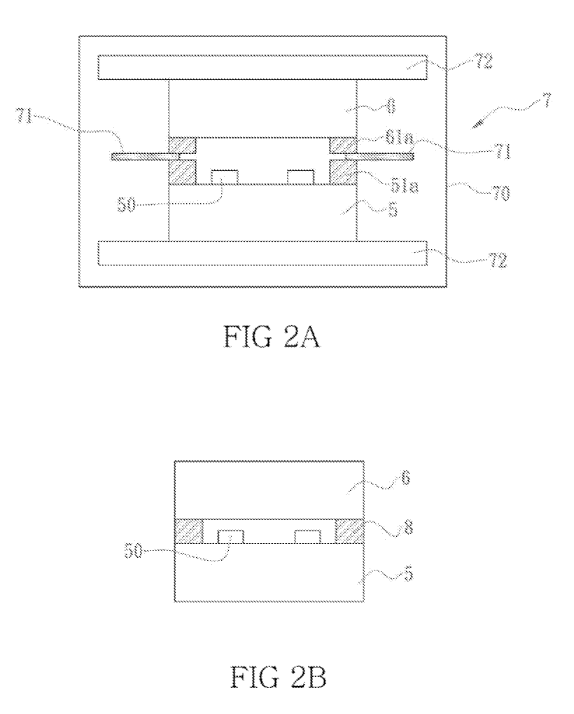

### DETAILED DESCRIPTION OF THE PREFERRED EMBODIMENT

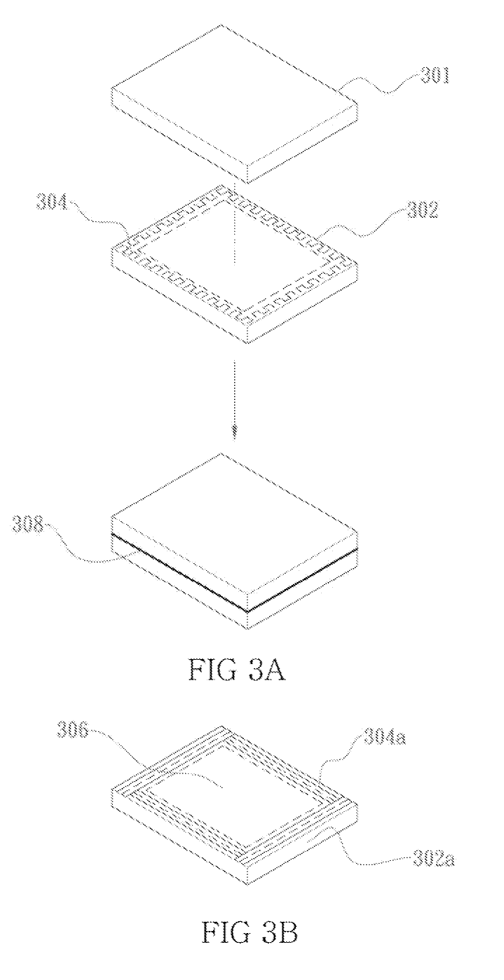

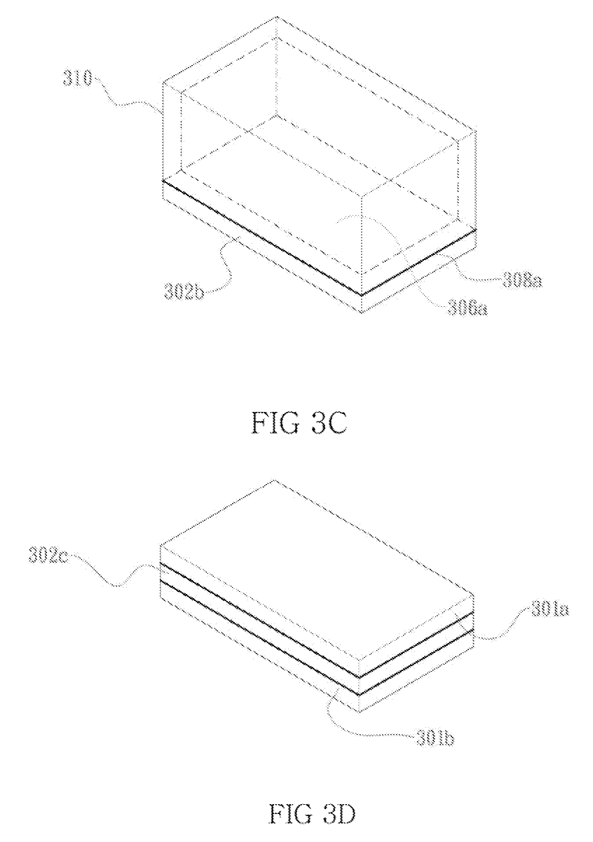

Referring to FIG. 3A, it is the analytic diagram of the partial bonding chip structure of an embodiment of the present invention. As shown in FIG. 3A, it is the partial bonding chip structure capable of being applied to the current semiconductor. The chip 300 comprises a Polymer layer 301, a substrate 302, and a metal layer 304. At first, the Polymer, such as poly-para-xylylene, is employed to accomplish good uniformity in spin-coating or chemical vapor deposition (CVD) method at low temperature. The polymer is employed to form the Polymer layer 301 in because of the characters, such as high informality, good flexibility, different hydrophilicity, low stress, low melting point, and high hermeticity, of the polymer, Next, the metal layer 304 is winded to work as a heating conductor, and surrounds the lateral side of the substrate to increase the current density to generate an adequate temperature. A last, the Polymer layer 301 and the substrate 302 are instantly bonded in part. There is a bonding area 308 formed between the two layers. The partially heating method is effectively employed to accomplish the bonding process of the chip 300 without affecting the internal circuit of the substrate 302.

Referring to FIG. 3A, it is the top view diagram of the partial bonding chip structure of an embodiment of the present invention. A substrate 302a is selected from a Si, GaAs, SiC, GaN or metal. A metal layer 304a, which is extremely thinned layer with a thickness ranged from tens amatrongs to hundrends amstrongs and surrounded around the lateral side of the substrate 302a, is provided to increase the current density without affecting characters of the internal circuit 306 of the substrate and the other materials. A metal layer (not shown) of the substrate is employed to be a heating conductor, and the current generates an adequate temperature so that the Polymer layer 301 and the substrate are hermetically bonded together in part without affecting the characters of the internal circuit and the other materials. As a result, the Polymer and the chip are bonded together to form an object with organism compatibility and fit for biomedical analysis.

Furthermore, referring to FIG. 3C, it is the diagram of a cavity of the present invention. As shown in FIG. 3C, the Polymer is employed to form a cavity 310. The cavity 310 and area of the lateral side of the substrate 302b are employed to be bonded together effectively. There is a bonding area 302a between the tow layers so that the structure in the chip can be operated unconstrained. As a result, it can be applied to the inertia sensor, pressure sensor, and fluid control.

In addition, referring to FIG. 3D, it is the diagram of the multi-layer metal structure of the present invention. As shown in FIG. 3D, the metal layer is multi-layer metal layer, comprising the metal layer clad in the Polymer. There are two Polymer layers 301a, 301b, and a substrate 302c is between the two Polymer; layers 301a, 301b. The partial bonding structure is accomplished in the external magnetic field or external inductive induction method.

It is noted that the partially bonding structure for the polymer and chip of the present invention employs the placed position of the metal layer to accomplish the partial heating effect without affecting the internal circuit of the chip.

It is noted that the partially bonding structure for the polymer and chip of the present invention employs the characters, such as high informality, good flexibility, different hydrophilicity, low stress, low melting point, and high hermeticity, of the polymer to form an object with organism compatibility and fit for biomedical analysis

One skilled in the art will understand that the embodiment of the present invention as shown in the drawings and described above is exemplary only and not intended to be limiting.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. An partially bonding structure for a Polymer and a chip, comprising:
a substrate;
a Polymer layer, formed on said substrate; and
a metal layer to . . ., employed to work as a heating conductor and to surround said substrate, wherein a current is employed to generate heat to partially bond said Polymer layer and said substrate without affecting said circuit.

2. The partially bonding structure for a Polymer and a chip according to the claim 1, wherein said metal layer is winded to increase a current density.

3. The partially bonding structure for a Polymer and a chip according to the claim 1, wherein a placed position of said metal layer is employed to define a heating range to accomplish a partial heating effect.

4. The partially bonding structure for a Polymer and a chip according to the claim 2, wherein a placed position of said metal layer is employed to define a heating range to accomplish a partial heating effect.

5. The partially bonding structure for a Polymer and a chip according to the claim 1, wherein said Polymer layer is formed by spin-coating or chemical vapor deposition.

6. The partially bonding structure for a Polymer and a chip according to the claim 1, wherein said substrate comprises silicon, gallium arsenide, silicon carbide, gallium nitride, or sapphire or matal.

7. The partially bonding structure for a Polymer and a chip according to the claim 1, wherein said structure is applied to a biomedical analysis or a fluid control.

8. A partially bonding structure for a Polymer and a chip a substrate, comprising a circuit on said substrate;
a cavity, formed by a Polymer layer on said substrate; and
a metal layer, employed to work as a heating conductor and to surround said substrate, wherein a current is employed to generate heat to partially bond said Polymer layer and said substrate so that said circuit work without affecting.

9. The partially bonding structure for a Polymer and a chip, according to the claim 8, wherein said metal layer is winded to increase a current density.

10. The partially bonding structure for a Polymer and a chip, according to the claim 8, a placed position of said metal layer is employed to define a heating range to accomplish a partial heating effect.

11. The partially bonding structure for a Polymer and a chip, according to the claim 9, wherein a placed position of said metal layer is employed to define a heating range to accomplish a partial heating effect.

12. The partially bonding structure for a Polymer and a chip, according to the claim 8, wherein said Polymer layer is formed by spin-coating or chemical vapor deposition.

13. The partially bonding structure for a Polymer and a chip, according to the claim 8, wherein said. substrate comprises silicon, gallium arsenide, silicon carbide, gallium nitride, or sapphire.

14. The partially bonding structure for a Polymer and a chip according to the claim 8, wherein said structure is applied to an inertia sensor, pressure sensor, biomedical analysis or a fluid control.

15. A partially bonding structure for a multi-layer metal and chip, comprising
a substrate, comprising a circuit on said substrate;
a metal layer, comprising multi-layer metal; and
a Polymer layer, formed on said substrate and covering said metal layer, wherein a current is employed to generate a heat bond said Polymer layer and said substrate.

16. The partially bonding structure for a multi-layer metal and chip according to the claim 15, wherein said metal layer is winded to increase a current density.

17. The partially bonding structure for a multi-layer metal and chip according to the claim 15, wherein a placed position of said metal layer is employed to define a heating range to accomplish a partial heating effect.

18. The partially bonding structure for a multi-layer metal and chip according to the claim 8, wherein a placed position of said metal layer is employed to define a heating range to accomplish a partial heating effect.

19. The partially bonding structure for a multi-layer metal and chip according to the claim 15, wherein said structure is formed by external magnetic field or external inductive induction.

20. The partially bonding structure for a multi-layer metal and chip according to the claim 15, wherein said Polymer layer is formed by spin-coating or chemical vapor deposition.

21. The partially bonding structure for a multi-layer metal and chip according to the claim 15, wherein said substrate comprises silicon, gallium arsenide, silicon carbide, gallium nitride, or sapphire,

22. The partially bonding structure for a Polymer and a chip according to the claim 15, wherein said structure is applied to a biomedical analysis or a fluid control.

23. An partially bonding structure for a Polymer and a chip, comprising:
a substrate;
a Polymer layer, formed on said substrate; and
a metal layer, employed to work as a heating conductor and to surround said substrate to partially bond said Polymer layer and said substrate without affecting said circuit.

24. The partially bonding structure for a Polymer and a chip according to the claim 23, wherein a placed position of said metal layer is employed to define a heating range to accomplish a partial heating effect.

25. The partially bonding structure for a Polymer and a chip according to the claim 23, wherein said Polymer layer is formed by spin-coating or chemical vapor deposition.

26. The partially bonding structure for a Polymer and a chip according to the claim 23, wherein said substrate comprises silicon, gallium arsenide, slicon carbide, gallium nitride, or sapphire.

27. The partially bonding structure for a Polymer and a chip according to the claim 23, wherein said structure is applied to a biomedical analysis or a fluid control.
